(19) United States
(12) Patent Application Publication
(10) Pub. No.: US 2013/0105756 A1
(43) Pub. Date: May 2, 2013

(54) PHASE-CHANGE MEMORY DEVICE

(71) Applicant: Tae-hoon Kim, Seoul (KR)

(72) Inventor: Tae-hoon Kim, Seoul (KR)

(73) Assignee: SAMSUNG ELECTRONICS CO., LTD., Suwon-si (KR)

(21) Appl. No.: 13/609,976

(22) Filed: Sep. 11, 2012

(30) Foreign Application Priority Data
Oct. 26, 2011 (KR) 10-2011-0110050

(51) Int. Cl. H01L 47/00

(52) U.S. Cl. 257/2; 257/E47.001

(57) ABSTRACT

A phase-change memory device comprises a first insulating layer on a substrate and a through hole formed in the first insulating layer. A first phase-change material layer is positioned along lower sidewalls and a lower face of the through hole. A second insulating layer is laterally surrounded by the first phase-change material layer. A second phase-change material layer is positioned along upper sidewalls of the through hole and in contact with upper surfaces of the first phase-change material layer and the second insulating layer.

### CROSS-REFERENCE TO RELATED APPLICATIONS

This application claims the benefit of Korean Patent Application No. 10-2011-0110050, filed on Oct. 26, 2011, in the Korean Intellectual Property Office, the disclosure of which is incorporated herein in its entirety by reference.

### BACKGROUND

The inventive concepts relate to memory devices, and more particularly, to non-volatile memory devices that employ a phase-change material.

The integration degree and operating speed of semiconductor devices, and, in particular, non-volatile memory devices, used in electronic products continue to increase at a rapid pace. A phase-change random access memory (PRAM) is a type of non-volatile memory device that employs a phase-change material as a storage element. The phase-change material may be considered a programmable resistive material that can be readily transformed between a high-resistance state and a low-resistance state. Such a state transformation of the phase-change material occurs in response to a change in the temperature thereof, and the temperature change may be induced through resistive heating. Resistive heating may be accomplished by supplying current between ends of the phase-change material. It is known that the resistance of a material interface is related to its contact area. That is, the smaller the contact area, the higher the resistance, and the higher the resistance, and the more effectively the phase-change material may be heated per unit of current, where current is directly related to power consumption.

### SUMMARY

The inventive concepts provide a phase-change memory device that may be operated with lower current, and, therefore, lower power consumption.

In an aspect of the inventive concepts, a phase-change memory device comprises: a first insulating layer on a substrate and including a through hole; a first phase-change material layer along lower sidewalls and a lower face of the through hole; a second insulating layer laterally surrounded by the first phase-change material layer; and a second phase-change material layer along upper sidewalls of the through hole and in contact with upper surfaces of the first phase-change material layer and the second insulating layer.

In some embodiments, the upper surface of the first phase-change material layer and the upper surface of the second insulating layer are at a same vertical position relative to the substrate.

In some embodiments, a height of the first phase-change material layer and a height of the second phase-change material layer in a vertical direction relative to the substrate are substantially the same.

In some embodiments, the first phase-change material layer and the second phase-change material layer each have a cup shape.

In some embodiments, the phase-change memory device further comprises a third insulating layer laterally surrounded by the second phase-change material layer.

In some embodiments, the second insulating layer and the third insulating layer each have a cylindrical shape or a truncated cone shape.

In some embodiments, the phase-change memory device further comprises an interfacial layer between the first phase-change material layer and the second phase-change material layer.

In some embodiments, the phase-change memory device further comprises: a first seed layer covering external side surfaces and a lower surface of the first phase-change material layer; and a second seed layer covering external side surfaces and a lower surface of the second phase-change material layer.

In some embodiments, the phase-change memory device further comprises impurities doped into the first phase-change material layer and the second phase-change material layer, wherein a content of the impurities doped into the second phase-change material layer is greater than a content of the impurities doped into the first phase-change material layer.

In some embodiments: a content of the impurities is about 14 to 16 wt % of the total weight of the first phase-change material layer, and a content of the impurities is about 17 to 19 wt % of the total weight of the second phase-change material layer.

In some embodiments, the phase-change memory device further comprises: a first electric conductor electrically connected to a lower surface of the first phase-change material layer; and a second electric conductor electrically connected to an upper surface of the second phase-change material layer.

In some embodiments, the second electric conductor comprises ring-shaped protrusions on a lower surface thereof.

In another aspect, a phase-change memory device comprises: a first insulating layer on a substrate and including a first electric conductor therein; a second insulating layer on the first insulating layer and including a through hole; a first phase-change material layer along a surface of the through hole and having a cup shape; and a second phase-change material layer on the first phase-change material layer, the second phase-change material layer being electrically connected to the first phase-change material layer and having a cup shape, wherein a content of impurities doped into the first phase-change material layer is less than a content of impurities doped into the second phase-change material layer.

In some embodiments, the second phase-change material layer is on the first phase-change material layer in contact with only upper surfaces of the first phase-change material layer.

In some embodiments, the second phase-change material layer is on the first phase-change material layer in such a manner that a lower surface of the second phase-change material layer contacts upper surfaces of the first phase-change material layer.

In another aspect, a phase-change memory device comprises: a first conductor; a first phase-change material layer having a base and sidewalls, the base of the first phase-change material layer being in contact with the first conductor; a first insulator on the base of the first phase-change material layer and laterally surrounded by the sidewalls of the first phase-change material layer; a second phase-change material layer having a base and sidewalls, the base of the second phase-change material layer being in contact with upper surfaces of the sidewalls of the first phase-change material layer; and a second conductor in contact with upper surfaces of the second phase change material layer.

In some embodiments, the phase-change memory device further comprises a second insulator on the base of the second phase-change material layer and laterally surrounded by the sidewalls of the second phase-change material layer.

In some embodiments, the first phase-change material layer and second phase-change material layer are each doped with impurities and wherein a doping concentration of impurities of the second phase-change material layer is greater than a doping concentration of impurities of the first phase-change material layer.

In some embodiments, the doping concentration of the impurities is about 14 to 16 wt % of the total weight of the first phase-change material layer, and the doping concentration of the impurities is about 17 to 19 wt % of the total weight of the second phase-change material layer.

In some embodiments, the phase-change memory device further comprises an insulating layer and wherein the first phase-change material layer and the second phase-change material layer are each formed as conformal layers at sidewalls of an opening in the insulating layer.

### BRIEF DESCRIPTION OF THE DRAWINGS

Exemplary embodiments of the inventive concepts will be more clearly understood from the following detailed description taken in conjunction with the accompanying drawings in which:

FIG. 1 is a schematic circuit diagram of a phase-change memory device according to an embodiment of the inventive concepts;

FIG. 2 is a schematic cross-sectional view of a phase-change memory device according to an embodiment of the inventive concepts;

FIG. 3 is a cross-sectional view taken along line I-I of FIG. 2 according to an embodiment of the inventive concepts;

FIG. 4 is a cross-sectional view taken along the line II-II of FIG. 2 according to an embodiment of the inventive concepts;

FIG. 5 is a schematic cross-sectional view of a phase-change memory device according to another embodiment of the inventive concepts;

FIG. 6 is a schematic cross-sectional view of a phase-change memory device according to another embodiment of the inventive concepts;

FIG. 7 is a schematic cross-sectional view of a phase-change memory device according to another embodiment of the inventive concepts;

FIG. 8 is a cross-sectional view taken along the line III-III of FIG. 7 according to an embodiment of the inventive concepts;

FIGS. 9 to 19 are cross-sectional views illustrating a method of fabricating the phase-change memory device of FIG. 1, according to an embodiment of the inventive concepts;

FIG. 20 is a schematic block diagram of a card according to an embodiment of the inventive concepts;

FIG. 21 is a schematic block diagram of a system according to an embodiment of the inventive concepts; and

FIG. 22 is a schematic perspective view of an electronic device that includes a semiconductor device, according to an embodiment of the inventive concepts.

### DETAILED DESCRIPTION OF EMBODIMENTS

The inventive concepts will now be described more fully hereinafter with reference to the accompanying drawings, in which exemplary embodiments of the inventive concept are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concept. In the drawings, embodiments of the inventive concepts are not limited to the specific examples provided herein and are exaggerated for clarity.

The terminology used herein is for the purpose of describing particular embodiments only and is not intended to limit. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present inventive concepts. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Hereinafter, embodiments of the inventive concepts will be described with reference to the drawings.

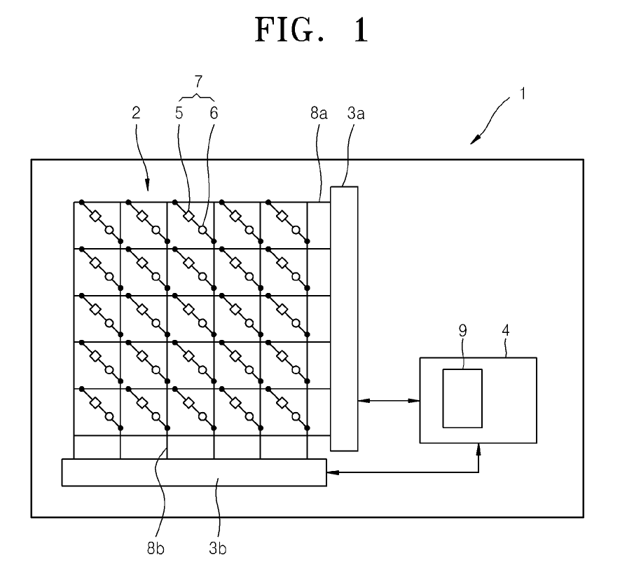

FIG. 1 is a schematic circuit diagram of a phase-change memory device 1 according to an embodiment of the inventive concepts. Referring to FIG. 1, the phase-change memory device 1 may include a phase-change memory array 2, a row decoder 3a, a column decoder 3b, and a control circuit 4.

The phase-change memory array 2 includes a plurality of unit cells 7 that are arranged in a matrix and each of which includes a memory part 5 and an access part 6.

The memory part 5 may include, in various embodiments, a phase-change material, a ferroelectric material, or a magnetic material. The state of the memory part 5 may vary according to the amount of current supplied thereto via a bit line (not shown). In this disclosure, phase-change memory devices according to embodiments of the inventive concept will be described with respect to a phase-change random access memory (PRAM) that employ a phase-change material. However, the inventive concepts are not limited thereto and may be applied to a resistive RAM (RRAM), a ferroelectric RAM (FRAM), a magnetic RAM (MRAM), or the like.

In a case where the memory part 5 includes a phase-change material layer (not shown), then the phase-change material layer has a crystalline state when the phase-change material layer is heated to a temperature between a crystallization temperature and a melting point thereof for a predetermined time and is then gradually cooled. The crystalline state is referred to as a ‘set state’. In some embodiments, the ‘set state’ can correspond to a data ‘0’ value. When the phase-change material layer is heated to a temperature that is equal to or greater than the melting point and is then quickly cooled, then the phase-change material layer has an amorphous state. The amorphous state is referred to as a ‘reset state’. In some embodiments, the ‘reset state’ can correspond to a data ‘1’ value. In other embodiments, the ‘set state’ can correspond to a data ‘1’ value and the ‘reset state’ can correspond to a data ‘0’ value.

Thus, data may be stored in accordance with a state of the phase-change material layer by supplying current to the phase-change material layer, and may be read by measuring a resistance value of the phase-change material layer. A temperature at which the phase-change material layer is heated is proportional to the amount of current supplied thereto. The greater the amount of current, the more difficult an integration degree of the phase-change memory device will be. Furthermore, the amount of current for switching the phase-change material layer to the amorphous state (reset state) is greater than that of current for switching the phase-change material layer to the crystalline state (set state). Thus, power consumption of the phase-change memory device 1 increases when the phase-change material layer is switched to the amorphous state (reset state) relative to the switch to the crystalline state. Embodiments of the present inventive concepts provide a phase-change material layer that reduces an operating current in order to reduce the power consumption of the resulting phase-change memory device 1.

The access part 6 controls the supply of current to the memory part 5 according to a voltage of a word line (not shown). In various embodiments, the access part 6 may be a diode, a bipolar transistor, or a MOS transistor, or other suitable switching device.

The plurality of memory unit cells 7 are electrically connected to first address lines 8a and second address lines 8b, respectively. The first address lines 8a and the second address lines 8b are arranged in two-dimensions at predetermined angles. The predetermined angles may be right angles, but are not limited thereto. In other embodiments, the first address lines 8a and the second address lines 8b are arranged transversely relative to each other. In various embodiments, the first address lines 8a or the second address lines 8b may be bit lines and the other may be word lines.

The row decoder 3a may communicate with the phase-change memory array 2 via the first address lines 8a. The column decoder 3b may communicate with the phase-change memory array 2 via the second address lines 8b.

The control circuit 4 may provide a row address signal to the row decoder 3a, and the row decoder 3a may decode the row address signal and provide the decoded row address signal to the phase-change memory array 2 via the first address lines 8a. The control circuit 4 may further provide a column address signal to the column decoder 3b, and the column decoder 3b may decode the column address signal and provide the decoded column address signal to the phase-change memory array 2 via the second address lines 8b. Although not shown, a sense amplifier and/or a page buffer may be disposed between the row decoder 3a and the control circuit 4 or between the column decoder 3b and the control circuit 4.

The control circuit 4 may include a power source circuit 9. The power source circuit 9 may stably supply current and/or voltage to the phase-change memory array 2 or may boost or lower an external voltage to a desired level, as required by the phase-change memory array 2. The power source circuit 9 may include a capacitor (not shown) to stably apply a high current and/or a high voltage. According to another embodiment of the inventive concepts, a plurality of phase-change material layers may be used to reduce an operating current.

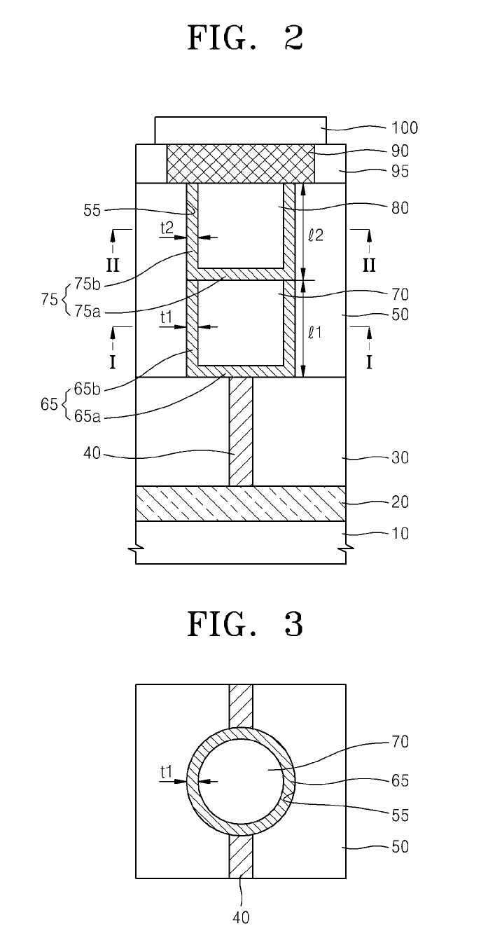

FIG. 2 is a schematic cross-sectional view of a phase-change memory device according to an embodiment of the inventive concepts. Referring to FIG. 2, the phase-change memory device may include a first variable resistor 65 positioned in a through hole 55 formed in a first insulating layer 50. A second variable resistor 75 is disposed on the first variable resistor 65. A first electric conductor 40 supplies a signal that changes resistance states of the first and second variable resistors 65 and 75. In addition, a second electric conductor 90 may be connected to the second variable resistor 75. Similar to the first electric conductor 40, the second electric conductor 90 may supply a signal for changing resistance states of the first and second variable resistors 65 and 75.

In some embodiments, a phase-change material may be used to form the first and second variable resistors 65 and 75. It is hereinafter assumed for purposes of the present disclosure that the first and second variable resistors 65 and 75 each comprise a phase-change material layer and referred to as the first and second phase-change material layers 65 and 75.

Each of the first and second phase-change material layers 65 and 75 may include a material that may be reversibly switched between a plurality of crystalline states that respectively denote different resistance states according to applied heat. In some embodiments, the number of crystalline states is two. In other embodiments, the number of crystalline states is three or more. An electrical signal, e.g., current or voltage, an optical signal, or radioactive rays may be employed to change crystalline states of the first and second phase-change material layers 65 and 75. For example, when current flows between the first and second electric conductors 40 and 90, heat is applied to the first and second phase-change material layers 65 and 75 through resistance heating and the crystalline states of the first and second phase-change material layers 65 and 75 may be changed according to the intensity of the heat.

The first phase-change material layer 65 may be formed of any of various materials that are reversibly switched between at least two states when an electrical signal, e.g., a current pulse, is supplied thereto via the first electric conductor 40. For example, the first phase-change material layer 65 may be a chalcogenide compound. Examples of the chalcogenide compound may include Ge—Sb—Te, As—Sb—Te, As—Ge—Sb—Te, Sn—Sb—Te, In—Sn—Sb—Te, Ag—In—Sb—Te, (a Group 15 element)—Sb—Te, (a Group 16 element)—Sb—Te, (a Group 15 element)—Sb—Se, (a Group 16 element)—Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, (a Group 15 element)—Sb—Te—Si, (a Group 16 element)—Sb—Te—Si, (a Group 15 element)—Sb—Se—Si, and (a Group 16 element)—Sb—Se—Si. Examples of impurities that can be doped into the chalcogenide compound may include carbon, nitrogen, oxygen, silicon, and a mixture thereof. The content, or concentration, of impurities doped into the chalcogenide compound used to form the first phase-change material layer 65 may be less than that of impurities doped into a chalcogenide compound used to form the second phase-change material layer 75. In some embodiments, the content of the impurities doped into the chalcogenide compound may be about 14 to 16 wt % of the total weight of the chalcogenide compound. For example, the content of the impurities may be 15 wt % of the total weight of the chalcogenide compound.

The second phase-change material layer 75 may be formed of any of various materials that are reversibly switched between at least two states when an electrical signal, e.g., a current pulse, is supplied thereto via the first phase-change material layer 65 and/or the second electric conductor 90. For example, the second phase-change material layer 75 may be a chalcogenide compound. Examples of the chalcogenide compound may include Ge—Sb—Te, As—Sb—Te, As—Ge—Sb—Te, Sn—Sb—Te, In—Sn—Sb—Te, Ag—In—Sb—Te, (a Group 15 element)—Sb—Te, (a Group 16 element)—Sb—Te, (a Group 15 element)—Sb—Se, (a Group 16 element)—Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, (a Group 15 element)—Sb—Te—Si, (a Group 16 element)—Sb—Te—Si, (a Group 15 element)—Sb—Se—Si, and (a Group 16 element)—Sb—Se—Si. Examples of impurities that can be doped into the chalcogenide compound may include carbon, nitrogen, oxygen, silicon, and a mixture thereof The content, or concentration, of impurities doped into the chalcogenide compound used to form the second phase-change material layer 75 may be greater than that of impurities doped into a chalcogenide compound used to form the first phase-change material layer 65. The content of the impurities doped into the chalcogenide compound may be about 17 to 19 wt % of the total weight of the chalcogenide compound. In some embodiments, the content of the impurities may be 18 wt % of the total weight of the chalcogenide compound.

In various embodiments, the through hole 55 in which the first and second phase-change material layers 65 and 75 are present may have, for example, a contact hole shape, a linear groove shape, a curved groove shape, or a combination of a linear groove shape and a curved groove shape. In other embodiments, the through hole may have another shape or shapes suitable for achieving the present inventive concepts.

The through hole 55 may include a lower face, sidewalls, and an upper face. The lower face of the through hole 55 may correspond to a portion of the through hole 55 adjacent to the first electric conductor 40. The sidewalls of the through hole 55 may correspond to side surfaces of the first insulating layer 50 that define the through hole 55. The upper face of the through hole 55 may be a portion of the through hole 55 that is opposite the first electric conductor 40, i.e., that is adjacent to the second electric conductor 90. Also, a portion of the sidewalls of the through hole 55 in which the first phase-change material layer 65 is provided will be referred to herein as ‘lower sidewalls’, and other portions of the sidewalls of the through hole 55 in which the second phase-change material layer 75 is provided is referred to herein as ‘upper sidewalls’.

A second insulating layer 70 may be provided on the lower face of, and between the lower sidewalls of, the through hole 55 on which the first phase-change material layer 65 is provided. The second insulating layer 70 may have a three-dimensional (3D) structure that fills a region covered by the first phase change material layer 65.

A third insulating layer 80 may be provided in an upper region of the through hole 55. In particular, the third insulating layer can be provided on the second phase change material layer 75. The third insulating layer may have a three-dimensional structure that fills a region covered by the second phase change material layer 75.

For example, the second insulating layer 70 may be formed apart from the first insulating layer 50 in a lower central part of the through hole 55, and the first phase-change material layer 65 may thus be formed in a space defined by the first insulating layer 50 and the second insulating layer 70. Also, the third insulating layer 80 may be formed apart from the first insulating layer 50 in a upper central part of the through hole 55, and the second phase-change material layer 75 may thus be formed in a space defined by the first insulating layer 50 and the third insulating layer 80.

In other words, the first phase-change material layer 65 may be formed to cover a lower surface of the second insulating layer 70 and side surfaces of the second insulating layer 70 adjacent to the lower surface, and the second phase-change material layer 75 may be formed to cover a lower surface of the third insulating layer 80 and side surfaces of the third insulating layer 80 adjacent to the lower surface. The second electric conductor 90 may be formed on the second phase-change material layer 75, the third insulating layer 80, and the first insulating layer 50.

A portion of the first phase-change material layer 65 disposed along the lower face of the through hole 55 and the other portion of the first phase-change material layer 65 disposed on the lower sidewalls of the through hole 55 will now be respectively referred to as a first part 65a and a second part 65b. In other words, the first part 65a of the first phase-change material layer 65 is disposed between the lower surface of the second insulating layer 70, between an interlayer insulating layer 30 and the first electric conductor 40, and the second part 65b of the first phase-change material layer 65 is disposed on the side surfaces of the second insulating layer 70. A portion of the second phase-change material layer 75 disposed on upper surfaces of the first phase-change material layer 65 and the second insulating layer 70 and a portion of the second phase-change material layer 75 disposed on the upper sidewalls of the through hole 55 will now be respectively referred to a first part 75a and a second part 75b. In other words, the first part 75a and the second part 75b of the second phase-change material layer 75 are respectively disposed on the lower surface of the third insulating layer 80 and on the side surfaces of the third insulating layer 80.

Thus, according to an embodiment of the inventive concepts, a portion of the first part 65a of the first phase-change material layer 65 contacts the first electric conductor 40, and only upper surfaces of the second part 65b are in contact with the second phase-change material layer 75. That is, the lower surface of the second phase-change material layer 75 may contact upper surfaces of the second part 65b of the first phase-change material layer 65.

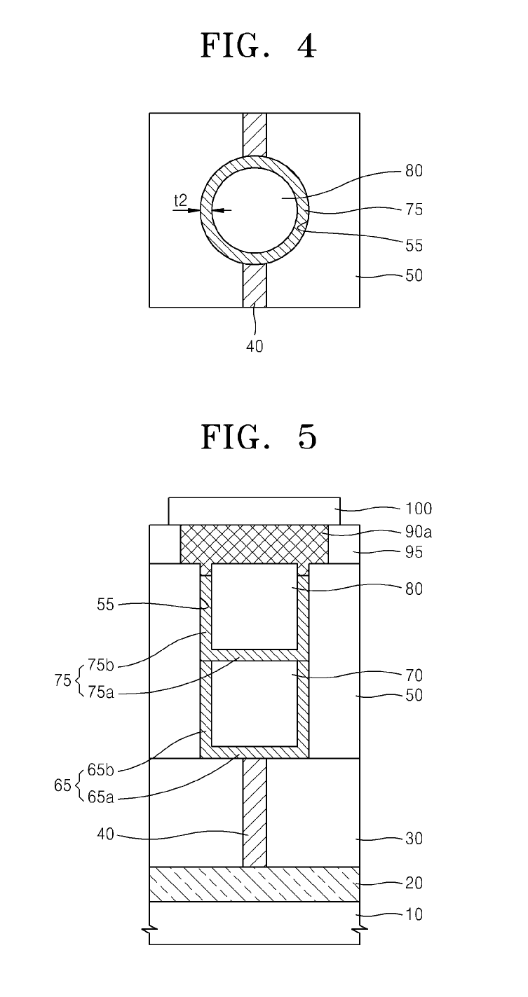

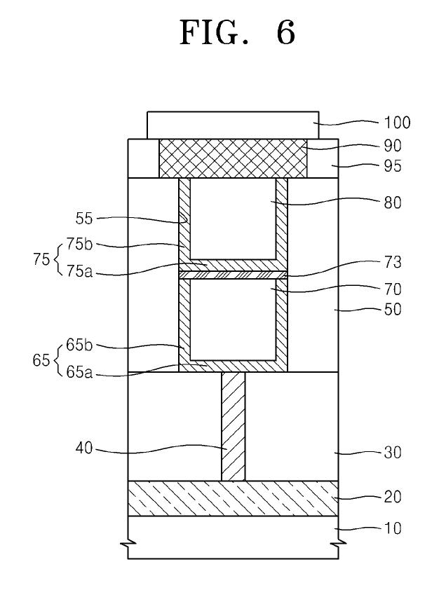

The shapes of the first and second phase-change material layers 65 and 75 have been described above with reference to FIG. 2, but the geometric shapes of the first and second phase-change material layers 65 and 75 will be clearly understood with reference to FIGS. 3 and 4.

FIG. 3 is a cross-sectional view taken along the line I-I of FIG. 2 in accordance with embodiments of the inventive concepts. FIG. 4 is a cross-sectional view taken along the line II-II of FIG. 2 in accordance with embodiments of the inventive concepts.

Referring to FIGS. 2 and 3, the through hole 55 in the first insulating layer 50 may have a contact hole shape. The contact hole shape is illustrated as a circular cross-sectional shape in FIGS. 2 and 3, but may have any of other various shapes in accordance with the manufacturing process used to form the hole. The second insulating layer 70 is provided in a lower central portion of the through hole 55 having the contact hole shape. The second insulating layer 70 may have any of a number of geometric forms, including a cylindrical or a truncated cone form. In some embodiments, the second part 65b (see FIG. 2) of the first phase-change material layer 65 may be disposed in a ring fashion on the lower sidewalls of the through hole 55. The first part 65a of the first phase-change material layer 65 is disposed on the lower face of the through hole 55. In this manner, the first phase-change material layer 65 may have a cup-shaped geometry; however, other forms or shapes are possible and within the scope of the present inventive concepts.

Referring to FIGS. 2 and 4, the through hole 55 in the first insulating layer 50 may have a contact hole shape. The contact hole shape is illustrated as a circular cross-sectional shape in FIGS. 3 and 4, but may have any of other various shapes in accordance with the manufacturing process used to form the hole. The third insulating layer 80 is provided in a upper central portion of the through hole 55 having the contact hole shape. The third insulating layer 80 may have any of a number of geometric forms, including a cylindrical or a truncated cone form. The second part 75b of the second phase-change material layer 75 may be disposed in a ring fashion on the upper sidewalls of the through hole 55, similar to the second part 65b of the first phase-change material layer 65. Also, the first part 75a of the second phase-change material layer 75 is disposed on the first phase-change material layer 65 and the second insulating layer 70. In this manner, the second phase-change material layer 75 may have a cup-shaped geometry, however, other forms or shapes are possible and within the scope of the present inventive concepts.

Referring back to FIG. 2, the first phase-change material layer 65 is formed on the lower face and lower sidewalls of the through hole 55 adjacent to, or otherwise in contact with, the first electric conductor 40. In an embodiment, the first phase-change material layer 65 may be formed to a thickness t1 on the lower face and lower sidewalls of the through hole 55 (or the side surfaces of the second insulating layer 70). Similarly, the second phase-change material layer 75 may be formed to a thickness t2 on the upper surface of the second insulating layer 70, the upper surfaces of the second part 75b of the second phase-change material layer 75, and the upper sidewalls of the through hole 55 (or the side surfaces of the third insulating layer 80). Here, the thickness t 1 of the first phase-change material layer 65 and the thickness t2 of the second phase-change material layer 75 are obtained by measuring the thicknesses of the sidewalls of the through hole 55 (or the thicknesses of the side surfaces of the second insulating layer 70 or the third insulating layer 80). According to an embodiment of the inventive concepts, the thicknesses t1 and t2 may be substantially the same; in other embodiments they may be different. According to an embodiment of the inventive concepts, the height f 1 of the first phase-change material layer 65 and the height l2 of the second phase-change material layer 75 may be substantially the same; in other embodiments, they may be different. According to embodiments of the inventive concepts, only a portion of the first phase-change material layer 65 is in contact with the first electric conductor 40 adjacent thereto, thereby reducing the contact region between the first phase-change material layer 65 and the first electric conductor 40. In this manner, the resistance of the interface is relatively increased, and therefore, an operating current for operating the first phase-change material layer 65 may be reduced.

Similarly, the second electric conductor 90 adjacent to the second phase-change material layer 75 is in contact with only upper surfaces of the second part 75b of the second phase-change material layer 75, thereby reducing a contact region between the second electric conductor 90 and the second phase-change material layer 75. In this manner, the resistance of the interface is relatively increased, and therefore the operating current for operating the second phase-change material layer 75 may be reduced.

Also, the upper surfaces of the second part 65b of the first phase-change material layer 65 contact only a portion of the first part 75a of the second phase-change material layer 75, thereby reducing a contact region between the first and second phase-change material layers 65 and 75. In this manner, the resistance of the interface is relatively increased, and therefore the operating current for operating the second phase-change material layer 75 may be reduced.

A reduction in the operating current leads to relatively lower power consumption and higher efficiency of the phase-change memory device.

The first electric conductor 40 may operate as a lower electrode of the phase-change memory device and may be electrically connected to a first interconnection layer 20 on a substrate 10.

The first electric conductor 40 may comprise, for example, at least one material selected from among metals, e.g., titanium, hafnium, zirconium, vanadium, niobium, tantalum, tungsten, aluminum, copper, titanium tungsten, and molybdenum; binary metallic nitrides, e.g., titanium nitride, hafnium nitride, zirconium nitride, vanadium nitride, niobium nitride, tantalum nitride, tungsten nitride, and molybdenum nitride; metallic oxides, e.g., an iridium oxide and a ruthenium oxide; ternary metal nitrides, e.g., titanium carbide nitride, tantalum carbide nitride, silicon titanium nitride, silicon tantalum nitride, aluminum titanium nitride, aluminum tantalum nitride, boron titanium nitride, silicon zirconium nitride, silicon tungsten nitride, boron tungsten nitride, aluminum zirconium nitride, silicon molybdenum nitride, aluminum molybdenum nitride, tantalum oxynitride, titanium oxynitride, tungsten oxynitride, and tantalum oxynitride; and silicon. In other embodiments, the first electric conductor 40 may comprise another suitably conductive material.

The second electric conductor 90 may operate as an upper electrode of the phase-change memory device and may be electrically connected to a second interconnection layer 100.

The second electric conductor 90 may comprise, for example, at least one material selected from among metals, e.g., titanium, hafnium, zirconium, vanadium, niobium, tantalum, tungsten, aluminum, copper, titanium tungsten, and molybdenum; binary metallic nitrides, e.g., titanium nitride, hafnium nitride, zirconium nitride, vanadium nitride, niobium nitride, tantalum nitride, tungsten nitride, and molybdenum nitride; metallic oxides, e.g., an iridium oxide and a ruthenium oxide; ternary metal nitrides, e.g., a titanium carbide nitride, a tantalum carbide nitride, a silicon titanium nitride, a silicon tantalum nitride, an aluminum titanium nitride, an aluminum tantalum nitride, a boron titanium nitride, a silicon zirconium nitride, a silicon tungsten nitride, a boron tungsten nitride, an aluminum zirconium nitride, a silicon molybdenum nitride, an aluminum molybdenum nitride, a tantalum oxynitride, a titanium oxynitride, a tungsten oxynitride, and a tantalum oxynitride; and silicon. In other embodiments, the second electric conductor 90 may comprise another suitably conductive material.

The interlayer insulating layer 30 and first to fourth insulating layers 50, 70, 80, and 95 may be each formed of, for example, at least one material selected from among silicon oxide, silicon nitride, and silicon oxynitride. In other embodiments, the insulating layers 30, 50, 70, 80 and 95 may comprise another suitably conductive material.

In some embodiments, the first and second interconnection layers 20 and 100 may be each comprise at least one material selected from among aluminum (Al), an aluminum-copper alloy (Al—Cu), an aluminum-copper-silicon alloy (Al—Cu—Si), tungsten silicide (WSi), copper (Cu), titanium tungsten (TiW), tantalum (Ta), molybdenum (Mo), and tungsten (W). In other embodiments, the first and second interconnection layers 20 and 100 may comprise another suitably conductive material.

In some embodiments, the first interconnection layer 20 may be used as a selection line for selecting the first and second phase-change material layers 65 and 75. In some embodiments, the second interconnection layer 100 may be used as a data line via which logic information stored in the first and second phase-change material layers 65 and 75 is delivered, i.e., a bit line.

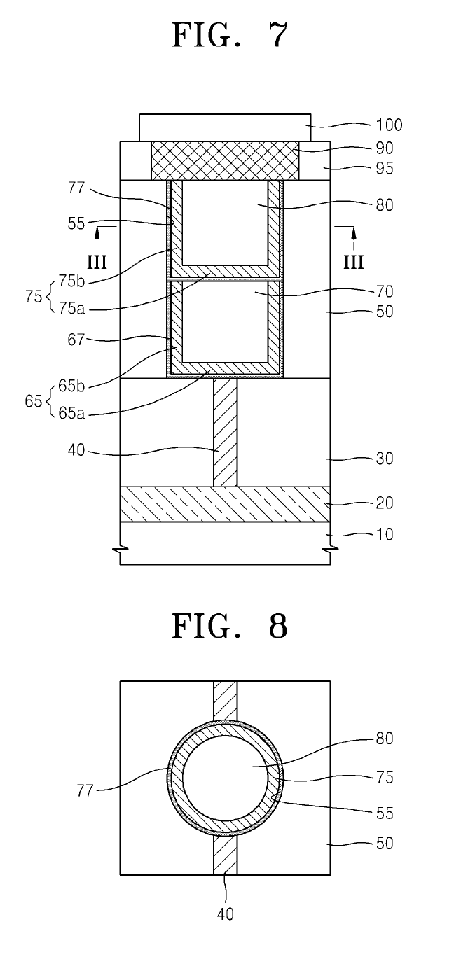

FIG. 5 is a schematic cross-sectional view of a phase-change memory device according to another embodiment of the inventive concepts. Referring to FIG. 5, a portion of a second electric conductor 90a may extend on upper sidewalls of the through hole 55, unlike in the phase-change memory device described above with reference to FIGS. 2 to 4. In other words, an upper surface of the second phase-change material layer 75 may be lower than that of a third insulating layer 80 and/or a first insulating layer 50. In the current embodiment, the second electric conductor 90a adjacent to the second phase-change material layer 75 may have a geometric shape in which ring-shaped protrusions are formed on a lower surface thereof.

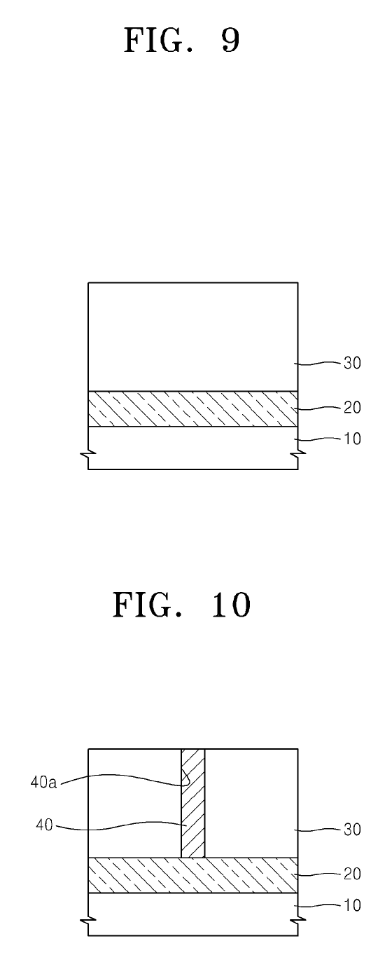

FIG. 6 is a schematic cross-sectional view of a phase-change memory device according to another embodiment of the inventive concepts. Referring to FIG. 6, an interfacial layer 73 may further be disposed between an upper portion of the first phase-change material layer 65 and a lower portion of the second phase-change material layer 75, as compared to the above embodiments wherein the upper portion of the first phase-change material layer 65 and the lower portion of the second phase-change material layer 75 are in direct contact with each other. In some embodiments, the interfacial layer 73 may be obtained by applying an interfacial material (not shown) on the first phase-change material layer 65 and the second insulating layer 70 and then performing an etch back process on the resulting structure. The interfacial layer 73 may comprise, for example, an oxide layer. In some embodiments, the thickness of the interfacial layer 73 may be about 2 to 4 Å. For example, in some embodiments, the thickness of the interfacial layer 73 may be 3 Å.

An interface resistance between the first and second phase-change material layers 65 and 75 may be increased by forming the interfacial layer 73 on the first phase-change material layer 65. Thus, it is possible to reduce the amount of current for performing Joule heating on the second phase-change material layer 75 on the first phase-change material layer 65.

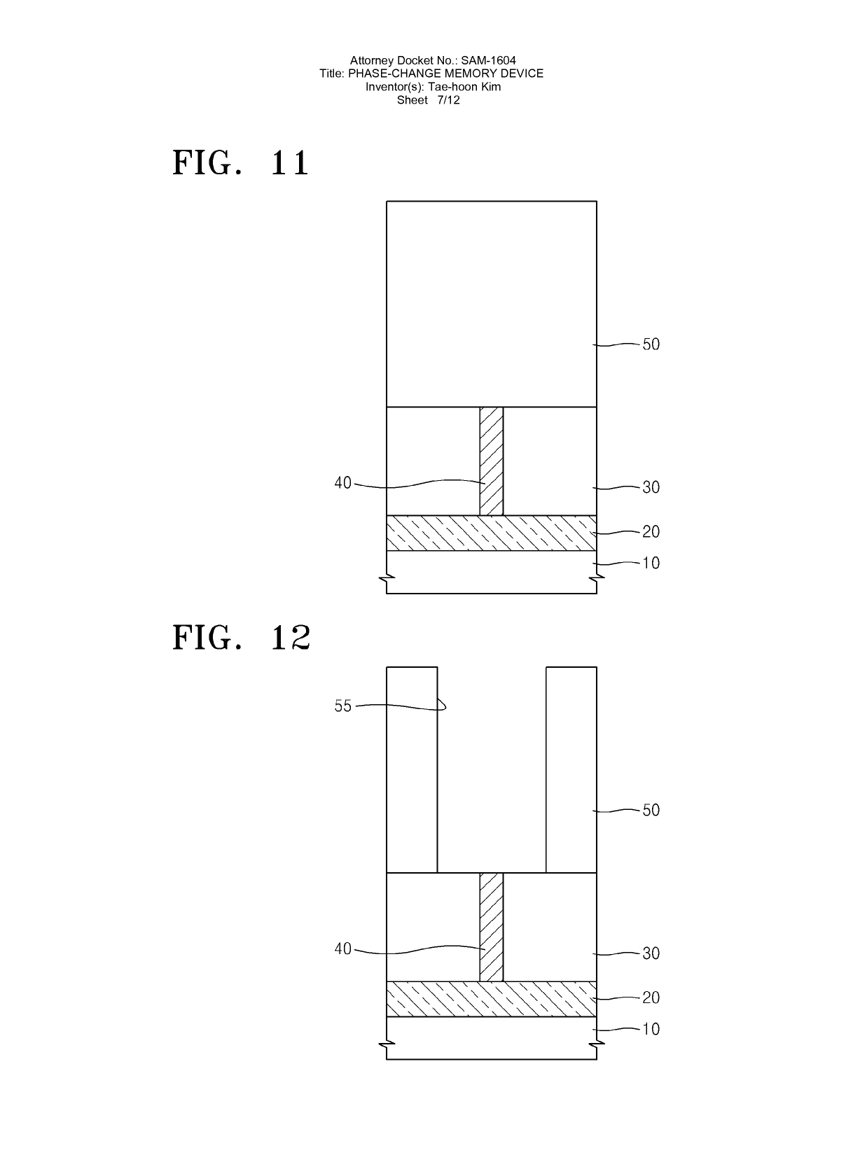

FIG. 7 is a schematic cross-sectional view of a phase-change memory device according to another embodiment of the inventive concepts. In this embodiment, the phase-change memory device of FIG. 7 may further include a first seed layer 67 and a second seed layer 77, relative to the phase-change memory devices described above with reference to FIGS. 2 to 6.

In some embodiments, the first seed layer 67 may be disposed between the first phase-change material layer 65 and the first insulating layer 50. In some embodiments, the first seed layer 67 may additionally be disposed between the first phase-change material layer 65, the interlayer insulating layer 30, and the first electric conductor 40. In other words, the first seed layer 67 can be positioned to cover external side surfaces and the lower surface of the first phase-change material layer 65. In some embodiments, the first seed layer 67 may have an amorphous composition. The first seed layer 67 allows the first phase-change material layer 65 to be evenly formed in a narrow region defined by the first insulating layer 50.

The second seed layer 77 may be disposed between the second phase-change material layer 75 and the first insulating layer 50. In some embodiments, the second seed layer 77 may additionally be disposed between the second phase-change material layer 75 and the second insulating layer 70 and between the second phase-change material layer 75 and the first phase-change material layer 65. In other words, the second seed layer 77 can be positioned to cover external side surfaces and the lower surface of the second phase-change material layer 75. In some embodiments, the second seed layer 77 may have an amorphous composition. In some embodiments, the second seed layer 77 allows the second phase-change material layer 75 to be evenly formed in a narrow region defined by the first insulating layer 50 and the second insulating layer 70.

The first and second seed layers 67 and 77 may comprise, for example, titanium oxide, tantalum oxide, zirconium oxide, hafnium oxide, magnesium oxide, indium oxide, niobium oxide, germanium oxide, antimony oxide, and tellurium oxide, or other suitable seed layer material.

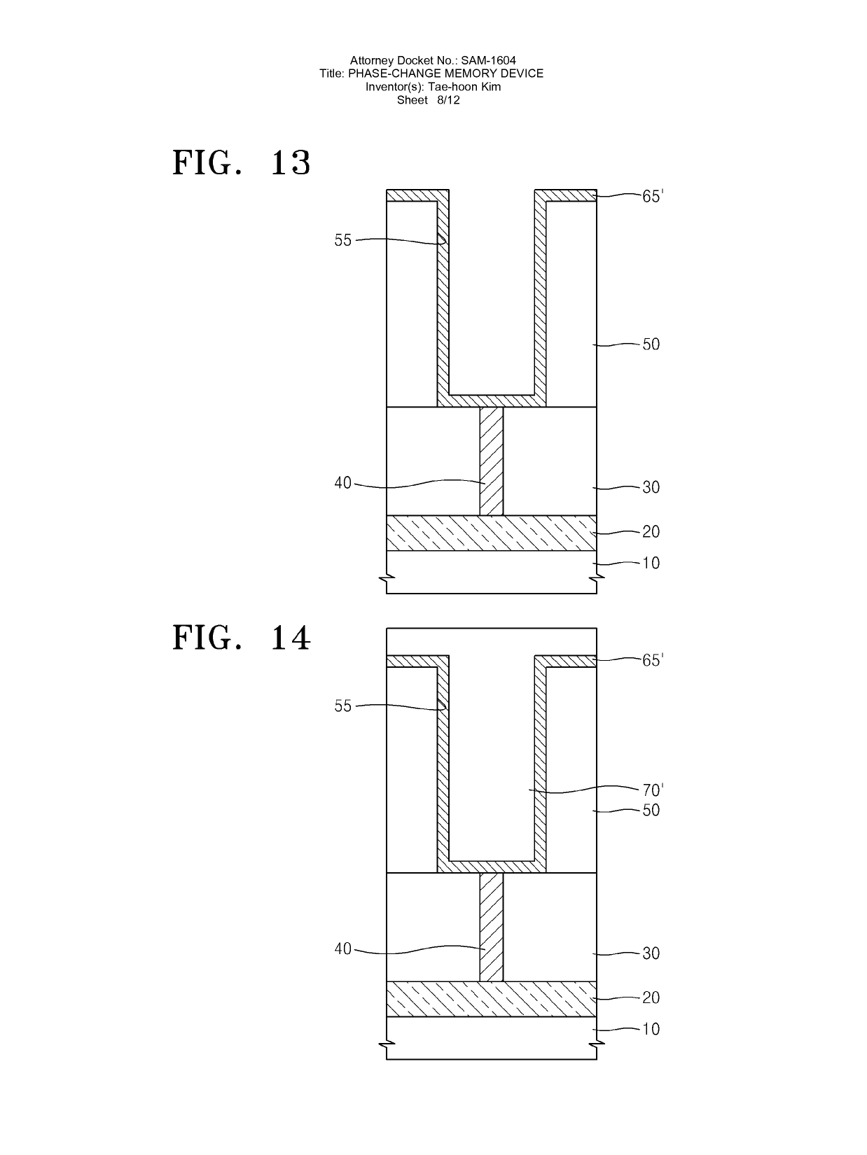

FIG. 8 is a cross-sectional view taken along the line III-III of FIG. 7. Referring to FIGS. 7 and 8, the second seed layer 77 is disposed between the second phase-change material layer 75 and the first and second insulating layers 50 and 70. Also, the second seed layer 77 is disposed between the second phase-change material layer 75, a second part 65b of the first phase-change material layer 65, and the second insulating layer 70. In other words, the second seed layer 77 covers the external side surfaces and lower surface of the second phase-change material layer 75.

The second seed layer 77 may have, for example, an amorphous state. In the current embodiment, assuming the presence of such first and second seed layers 67, 77, the thicknesses of the first and second phase-change material layers 65 and 75 may be respectively narrower than the thicknesses t1 and t2.

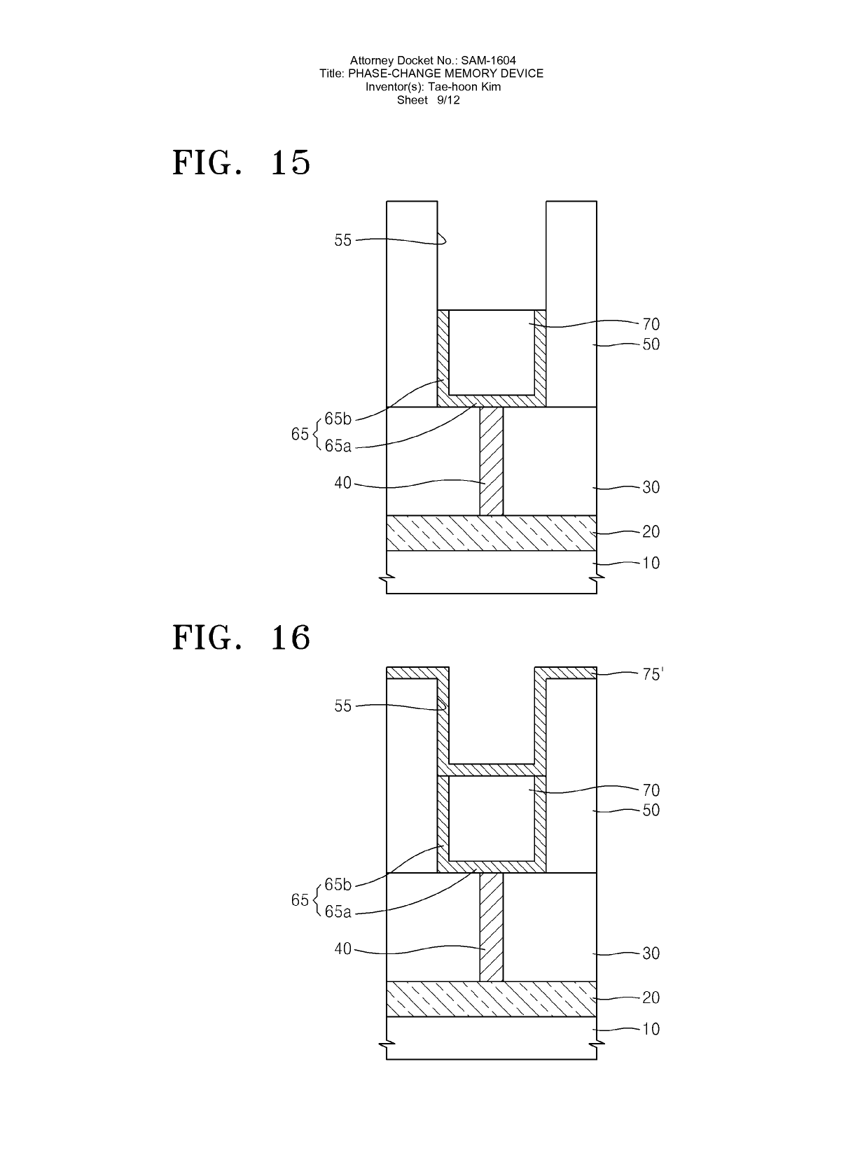

FIGS. 9 to 19 are cross-sectional views illustrating a method of fabricating the phase-change memory device 1 of FIG. 1, according to an embodiment of the inventive concepts. Referring to FIG. 9, a first interconnection layer 20 and an interlayer insulating layer 30 may be sequentially formed on a substrate 10.

In some embodiments, the substrate 10 may include a dielectric layer formed of silicon oxide, titanium oxide, aluminum oxide, zirconium oxide, or hafnium oxide; a conductive layer formed of titanium (Ti), titanium nitride (TiN), aluminum (Al), tantalum (Ta), tantalum nitride (TaN) and/or titanium aluminum nitride (TiAlN); or a semiconductor layer formed of silicon (Si), silicon-germanium (SiGe), and/or silicon carbide (SiC). Also, the substrate 10 may include an epitaxial layer, a silicon-on-insulator (SOI) layer, and/or a semiconductor-on-insulator (SOI) layer, or other suitable substrate material.

In some embodiments, the first interconnection layer 20 may formed of at least one material selected from among aluminum (Al), an aluminum-copper alloy (Al—Cu), an aluminum-copper-silicon alloy (Al—Cu—Si), tungsten silicide (WSi), copper (Cu), titanium tungsten (TiW), tantalum (Ta), molybdenum (Mo), and tungsten (W), or other suitable conductive layer. In some embodiments, the first interconnection layer 20 may be used as a selection line for selecting first and second phase-change material layers 65 and 75 of FIG. 19.

In some embodiments, the interlayer insulating layer 30 may be formed of at least one material selected from among silicon nitride and silicon oxynitride, or other suitable insulating material.

Referring to FIG. 10, an aperture 40a is formed in the interlayer insulating layer 30 until the first interconnection layer 20 is exposed.

Then, a conductive material is applied into the aperture 40a to form a first electric conductor 40. In some embodiments, the first electric conductor 40 may be used as a lower electrode of the phase-change memory device 1 and may be electrically connected to the first interconnection layer 20 on the substrate 10.

In various embodiments, the first electric conductor 40 may be formed of, for example, at least one material selected from among metals, e.g., titanium, hafnium, zirconium, vanadium, niobium, tantalum, tungsten, aluminum, copper, titanium tungsten, and molybdenum; binary metallic nitrides, e.g., titanium nitride, hafnium nitride, zirconium nitride, vanadium nitride, niobium nitride, tantalum nitride, tungsten nitride, and molybdenum nitride; metallic oxides, e.g., iridium oxide and ruthenium oxide; ternary metal nitrides, e.g., titanium carbide nitride, tantalum carbide nitride, silicon titanium nitride, silicon tantalum nitride, aluminum titanium nitride, aluminum tantalum nitride, boron titanium nitride, silicon zirconium nitride, silicon tungsten nitride, boron tungsten nitride, aluminum zirconium nitride, silicon molybdenum nitride, aluminum molybdenum nitride, tantalum oxynitride, titanium oxynitride, tungsten oxynitride, and tantalum oxynitride; and silicon. In other embodiments, the first electric conductor 40 may be formed of another suitable conductive material.

Referring to FIG. 11, a first insulating layer 50 is formed on the interlayer insulating layer 30 and the first electric conductor 40. The first insulating layer 50 may be formed of, for example, at least one material selected from among silicon oxide, silicon nitride, and silicon oxynitride.

Referring to FIG. 12, a through hole 55 is defined in the first insulating layer 50. The through hole 55 may be formed, for example, by removing a portion of the first insulating layer 50 according to a photolithographic process. The through hole 55 may have, for example, a contact hole shape, a linear groove shape, a curved groove shape, or a combination of the linear groove shape and the curved groove shape. In some embodiments, the through hole 55 may include a lower face, sidewalls, and an upper face.

Referring to FIG. 13, a first phase-change material 65′ is applied onto the sidewalls and lower face of the through hole 55. In some embodiments, the first-phase change material 65′ comprises a conformal layer that does not fill the through hole 55.

A first phase-change material 65′ may be any of various materials that are reversibly switched between at least two states when an electrical signal, e.g., a current pulse, is supplied thereto via the first electric conductor 40. For example, the first phase-change material 65′ may include a chalcogenide compound. Examples of the chalcogenide compound may include Ge—Sb—Te, As—Sb—Te, As—Ge—Sb—Te, Sn—Sb—Te, In—Sn—Sb—Te, Ag—In—Sb—Te, (a Group 15 element)—Sb—Te, (a Group 16 element)—Sb—Te, (a Group 15 element)—Sb—Se, (a Group 16 element)—Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, (a Group 15 element)—Sb—Te—Si, (a Group 16 element)—Sb—Te—Si, (a Group 15 element)—Sb—Se—Si, and (a Group 16 element)—Sb—Se—Si. In some embodiments, the first phase-change material 65′ comprises another suitable phase change material.

A content, or concentration, of impurities doped into the chalcogenide compound of the first phase-change material 65′ may be less than that of impurities doped into a chalcogenide compound used to form a second phase-change material 75′ (see FIG. 16). Examples of impurities doped into the chalcogenide compound may include carbon, nitrogen, oxygen, silicon, and a mixture thereof. In some embodiments, the content of the impurities of the first phase-change material 65′ may be about 14 to 16 wt % of the total weight of the chalcogenide compound. For example, the content of the impurities first phase-change material 65′ may be 15 wt % of the total weight of the chalcogenide compound.

Referring to FIG. 14, a second insulating material 70′ is applied onto the first phase-change material 65′ so that the through hole 55 may be filled with the second insulating material 70′.

The second insulating material 70′ may be used as an insulating spacer of the first phase-change material layer 65 (see FIG. 15). The second insulating material 70′ may include at least one material selected from among silicon oxide and silicon nitride, or other suitable insulating materials.

Then, referring to FIGS. 14 and 15, the second insulating material 70′ and the first phase-change material 65′ are selectively, partially removed by a chemical mechanical polishing (CMP) process, an etch back process, or a combination of the CMP process and the etch back process, thereby forming a first phase-change material layer 65 and a second insulating layer 70 in a portion of through hole 55. As a result of the partial removal, an upper surface of the first phase-change material layer 65 and an upper surface of the second insulating layer 70 may be flush with each other. In other embodiments, the upper surfaces 65, 70 are not flush, but instead are at different vertical positions as a result of the partial removal.

The first phase-change material layer 65 may include a first part 65a positioned or disposed on the lower face of through hole 55 and a second part 65b positioned or disposed on the lower sidewalls of the through hole 55. In other words, the first part 65a and the second part 65b of the first phase-change material layer 65 may be respectively disposed on a lower surface of the second insulating layer 70 and side surfaces of the second insulating layer 70.

The second insulating layer 70 may have a three-dimensional (3D) structure in which a first surface and a second surface face each other and a third surface connects the first and second surfaces, or that otherwise fills a region covered by the first phase change material layer 65.

The first phase-change material layer 65 may have a cup shape, and the second insulating layer 70 may have a cylindrical shape or a truncated cone shape.

Since the first phase-change material layer 65 has a cup shape, the resulting contact region between the first phase-change material layer 65 and the first electric conductor 40 is therefore reduced.

Referring to FIG. 16, the second phase-change material 75′ is applied on the upper surfaces of the first phase-change material layer 65 and the second insulating layer 70, upper sidewalls of the through hole 55, and an upper surface of the first insulating layer 50.

The second phase-change material 75′ may comprise any of a number of various materials that are reversibly switched between at least two states when an electrical signal, e.g., a current pulse, is supplied thereto via the first phase-change material layer 65. For example, the second phase-change material 75′ may be a chalcogenide compound. Examples of the chalcogenide compound may include Ge—Sb—Te, As—Sb—Te, As—Ge—Sb—Te, Sn—Sb—Te, In—Sn—Sb—Te, Ag—In—Sb—Te, (a Group 15 element)—Sb—Te, (a Group 16 element)—Sb—Te, (a Group 15 element)—Sb—Se, (a Group 16 element)—Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, (a Group 15 element)—Sb—Te—Si, (a Group 16 element)—Sb—Te—Si, (a Group 15 element)—Sb—Se—Si, and (a Group 16 element)—Sb—Se—Si. In some embodiments, the first phase-change material 65′ comprises another suitable phase change material.

The concentration or content of impurities doped into the chalcogenide compound of the second phase-change material 75′ may be greater than that of impurities doped into the chalcogenide compound of the first phase-change material layer 65′ of FIG. 13. Examples of the impurities doped into the chalcogenide compound may include carbon, nitrogen, oxygen, silicon, and a mixture thereof. In some embodiments, the content of the impurities to that of the chalcogenide compound of the second phase-change material 75′ may be about 17 to 19 wt % of the total weight of the chalcogenide compound. For example, the content of the impurities to that of the chalcogenide compound of the second phase-change material 75′ may be 18 wt % of the total weight of the chalcogenide compound.

Referring to FIG. 17, a third insulating material 80′ is applied onto the second phase-change material 75′ so that the through hole 55 may be filled with the third insulating material 80′. The third insulating material 80′ may act as an insulating spacer of the second phase-change material layer 75 illustrated in FIG. 18.

In some embodiments, the third insulating material 80′ may include, for example, a silicon oxide, a silicon nitride, a silicon oxynitride, and a mixture thereof, or other suitable insulating material.

Referring to FIG. 18, portions of the third insulating material 80′ and the second phase-change material 75′, which are exposed beyond the through hole 55 are removed according to a CMP process, an etch back process, or a combination of the CMP process and the etch back process, thereby forming the second phase-change material layer 75 and a third insulating layer 80 in a space defined by the through hole 55.

The second phase-change material layer 75 may have a first part 75a disposed on the upper surfaces of the first phase-change material layer 65 and the second insulating layer 70, and a second part 75b disposed on the upper sidewalls of the through hole 55. In other words, the first part 75a and the second part 75b of the second phase-change material layer 75 are respectively disposed on a lower surface of the third insulating layer 80 and side surfaces of the third insulating layer 80.

The third insulating layer 80 may have a three-dimensional (3D) structure in which a first surface and a second surface face each other and a third surface connects the first and second surfaces, or that otherwise fills a region covered by the first phase change material layer 65.

In some embodiments, the lateral thickness t2 of the second phase-change material layer 75 and the lateral thickness t1 of the first phase-change material layer 65 may be substantially the same; in other embodiments, they may differ. Also, in some embodiments, the height l2 of the second phase-change material layer 75 and the height l1 of the first phase-change material layer 65 may be substantially the same; in other embodiments, they may differ.

The lower surface of the second phase-change material layer 75 contacts the upper surfaces of the second part 65b of the first phase-change material layer 65 having a cup shape covering the second insulating layer 70, thereby reducing the contact region between the first and second phase-change material layers 65 and 75. As a result, in the phase-change memory device 1, an operating voltage for operating the second phase-change material layer 75 may be reduced. A reduction in the operating voltage leads to relatively low power consumption and relatively high efficiency of the phase-change memory device 1.

Then, referring to FIG. 19, a fourth insulating layer 95 is formed on exposed upper surfaces of the second phase-change material layer 75 and the third insulating layer 80.

The fourth insulating layer 95 may be formed of, for example, a silicon oxide, a silicon nitride, a silicon oxynitride, or a mixture thereof.

Then, a second electric conductor 90 is formed through the fourth insulating layer 95 to be connected to the second phase-change material layer 75. The second electric conductor 90 may operate as an upper electrode of the phase-change memory device 1.

In various embodiments, the second electric conductor 90 may be formed of, for example, at least one material selected from among metals, e.g., titanium, hafnium, zirconium, vanadium, niobium, tantalum, tungsten, aluminum, copper, titanium tungsten, and molybdenum; binary metallic nitrides, e.g., titanium nitride, hafnium nitride, zirconium nitride, vanadium nitride, niobium nitride, tantalum nitride, tungsten nitride, and molybdenum nitride; metallic oxides, e.g., iridium oxide and ruthenium oxide; ternary metal nitrides, e.g., titanium carbide nitride, tantalum carbide nitride, silicon titanium nitride, silicon tantalum nitride, aluminum titanium nitride, aluminum tantalum nitride, boron titanium nitride, silicon zirconium nitride, silicon tungsten nitride, boron tungsten nitride, aluminum zirconium nitride, silicon molybdenum nitride, aluminum molybdenum nitride, tantalum oxynitride, titanium oxynitride, tungsten oxynitride, and tantalum oxynitride; and silicon, or other suitable conductive material.

Then, a second interconnection layer 100 may be formed on the second electric conductor 90. In some embodiments, the second interconnection layer 100 may be used as a data line via which logic information stored in the first and second phase-change material layers 65 and 75 is delivered, i.e., a bit line.

In various embodiments, the second interconnection layer 100 may be formed of at least one material selected from among aluminum (Al), an aluminum-copper alloy (Al—Cu), an aluminum-copper-silicon alloy (Al—Cu—Si), tungsten silicide (WSi), copper (Cu), titanium tungsten (TiW), tantalum (Ta), molybdenum (Mo), and tungsten (W), or other suitable materials.

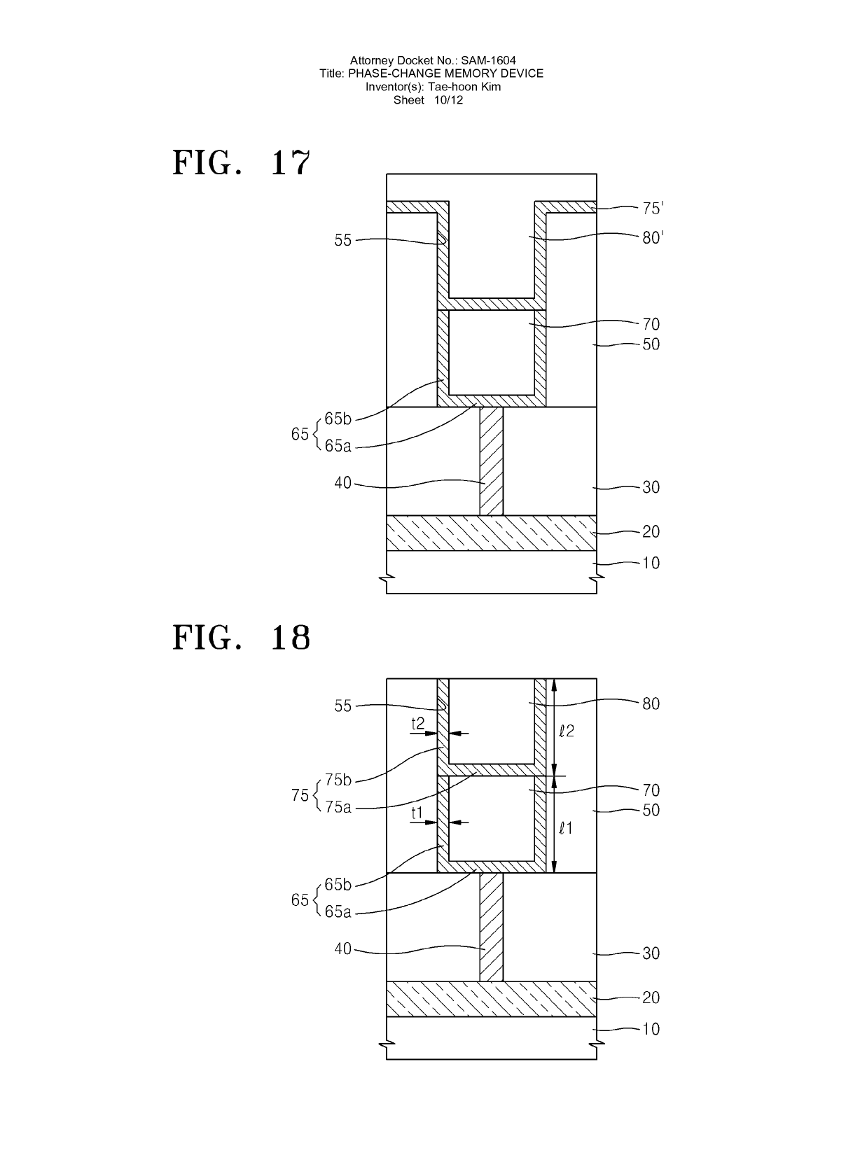

FIG. 20 is a schematic block diagram of a card 200 according to an embodiment of the inventive concept. Referring to FIG. 20, a controller 210 and a memory 220 may be disposed to exchange an electrical signal with each other. For example, when the controller 210 provides a command to the memory 220, the memory 220 may transmit data to the controller 210. The memory 220 may include one of the phase-change memory devices according to the above embodiments. As well known in the technical field to which the inventive concept pertains, phase-change memory devices according to various embodiments of the inventive concept may each be arranged in an architecture memory array (not shown) corresponding to the design of a corresponding logic gate. A memory array in which a plurality of unit cells are arranged in a matrix consisting of a plurality of rows and a plurality of columns may form at least one memory array bank (not shown). Although not shown, the memory 220 may include such a memory array or memory array bank. Although not shown, the card 200 may further include a general row decoder, a column decoder, input/output (I/O) buffers, and/or a control register in order to drive the memory array bank. The card 200 may be applied to various types of cards, e.g., a memory stick card, a smart media (SM) card, a secure digital (SD) card, a mini SD card; and a multi media card (MMC).

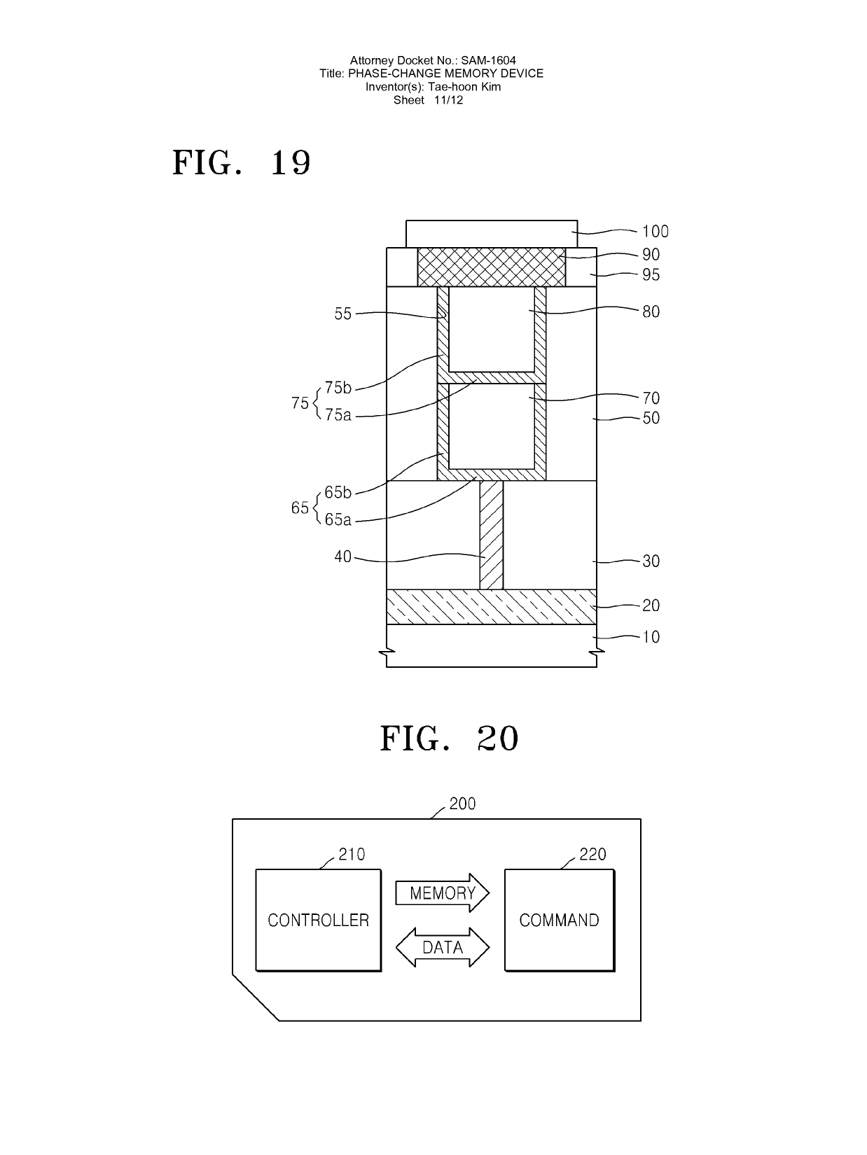

FIG. 21 is a schematic block diagram of a system 300 according to an embodiment of the inventive concept. Referring to FIG. 21, the system 300 may include a controller 310, an I/O device 320, a memory 330, and an interface 340. The system 300 may be a mobile system or a system capable of transmitting or receiving information. Examples of the mobile system may include a personal digital assistant (PDA), a portable computer, a web tablet, a wireless phone, a mobile phone, a digital music player, and a memory card.

The controller 310 may run a program and control the system 300. The controller 310 may be a microprocessor, a digital signal processor, a microcontroller, or the like.

The I/O device 320 may be used to input data to or output data from the system 300. The system 300 may be connected to an external device, e.g., a personal computer (PC) or a network, via the I/O device 320 so as to exchange data with the external device. The I/O device 320 may be, for example, a keypad, a keyboard, or a display.

The memory 330 may store code and/or data for operating the controller 310, and/or store data processed by the controller 310. The memory 330 may include one of the phase-change memory devices according to the above embodiments.

The interface 340 may be a data transmission path between the system 300 and an external device. The controller 310, the I/O device 320, the memory 330, and the interface 340 may communicate with one another via a bus 350. For example, the system 300 may be used in a mobile phone, an MP3 player, a navigator, a portable multimedia player (PMP), a solid state disk (SSD), or household appliances.

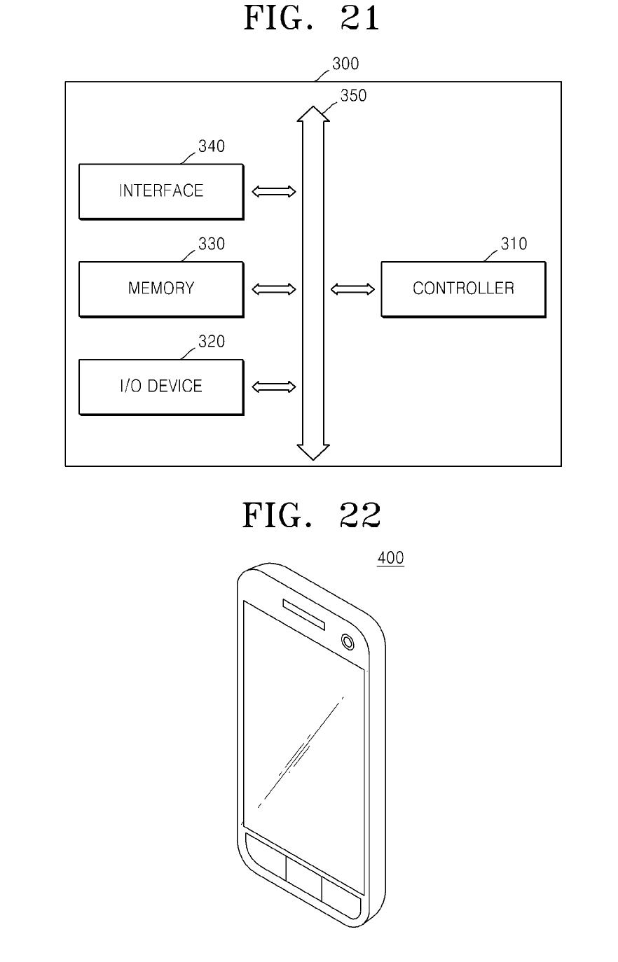

FIG. 22 is a schematic perspective view of an electronic device 400 that includes a semiconductor device, according to an embodiment of the inventive concept. FIG. 22 illustrates a case where an electronic system, such as the system 300 of FIG. 21, is applied to the electronic device 400, e.g., a mobile phone. Furthermore, the electronic system may be applied to a portable notebook computer, a tablet computer, an MP3 player, a navigator, an SSD, a car, or household appliances.

While the inventive concepts have been particularly shown and described with reference to exemplary embodiments thereof, it will be understood that various changes in form and details may be made herein without departing from the spirit and scope of the following claims.

What is claimed is:

1. A phase-change memory device comprising:
a first insulating layer on a substrate and including a through hole;
a first phase-change material layer along lower sidewalls and a lower face of the through hole;
a second insulating layer laterally surrounded by the first phase-change material layer; and
a second phase-change material layer along upper sidewalls of the through hole and in contact with upper surfaces of the first phase-change material layer and the second insulating layer.

2. The phase-change memory device of claim 1, wherein the upper surface of the first phase-change material layer and the upper surface of the second insulating layer are at a same vertical position relative to the substrate.

3. The phase-change memory device of claim 1, wherein a height of the first phase-change material layer and a height of the second phase-change material layer in a vertical direction relative to the substrate are substantially the same.

4. The phase-change memory device of claim 1, wherein the first phase-change material layer and the second phase-change material layer each have a cup shape.

5. The phase-change memory device of claim 1, further comprising a third insulating layer laterally surrounded by the second phase-change material layer.

6. The phase-change memory device of claim 5, wherein the second insulating layer and the third insulating layer each have a cylindrical shape or a truncated cone shape.

7. The phase-change memory device of claim 1, further comprising an interfacial layer between the first phase-change material layer and the second phase-change material layer.

8. The phase-change memory device of claim 1, further comprising:
a first seed layer covering external side surfaces and a lower surface of the first phase-change material layer; and
a second seed layer covering external side surfaces and a lower surface of the second phase-change material layer.

9. The phase-change memory device of claim 1, further comprising impurities doped into the first phase-change material layer and the second phase-change material layer,
wherein a content of the impurities doped into the second phase-change material layer is greater than a content of the impurities doped into the first phase-change material layer.

10. The phase-change memory device of claim 9, wherein:
a content of the impurities is about 14 to 16 wt % of the total weight of the first phase-change material layer, and
a content of the impurities is about 17 to 19 wt % of the total weight of the second phase-change material layer.

11. The phase-change memory device of claim 1, further comprising:
a first electric conductor electrically connected to a lower surface of the first phase-change material layer; and
a second electric conductor electrically connected to an upper surface of the second phase-change material layer.

12. The phase-change memory device of claim 11, wherein the second electric conductor comprises ring-shaped protrusions on a lower surface thereof.

13. A phase-change memory device comprising:
a first insulating layer on a substrate and including a first electric conductor therein;
a second insulating layer on the first insulating layer and including a through hole;
a first phase-change material layer along a surface of the through hole and having a cup shape; and
a second phase-change material layer on the first phase-change material layer, the second phase-change material layer being electrically connected to the first phase-change material layer and having a cup shape,
wherein a content of impurities doped into the first phase-change material layer is less than a content of impurities doped into the second phase-change material layer.

14. The phase-change memory device of claim 13, wherein the second phase-change material layer is on the first phase-change material layer in contact with only upper surfaces of the first phase-change material layer.

15. The phase-change memory device of claim 13, wherein the second phase-change material layer is on the first phase-change material layer in such a manner that a lower surface of the second phase-change material layer contacts upper surfaces of the first phase-change material layer.

16. A phase-change memory device comprising:
a first conductor;
a first phase-change material layer having a base and sidewalls, the base of the first phase-change material layer being in contact with the first conductor;
a first insulator on the base of the first phase-change material layer and laterally surrounded by the sidewalls of the first phase-change material layer;
a second phase-change material layer having a base and sidewalls, the base of the second phase-change material layer being in contact with upper surfaces of the sidewalls of the first phase-change material layer; and
a second conductor in contact with upper surfaces of the second phase change material layer.

17. The phase-change memory device of claim 16 further comprising a second insulator on the base of the second phase-change material layer and laterally surrounded by the sidewalls of the second phase-change material layer.

18. The phase-change memory device of claim 16 wherein the first phase-change material layer and second phase-change material layer are each doped with impurities and wherein a doping concentration of impurities of the second phase-change material layer is greater than a doping concentration of impurities of the first phase-change material layer.

19. The phase-change memory device of claim 18, wherein:
the doping concentration of the impurities is about 14 to 16 wt % of the total weight of the first phase-change material layer, and
the doping concentration of the impurities is about 17 to 19 wt % of the total weight of the second phase-change material layer.

20. The phase change memory device of claim 16 further comprising an insulating layer and wherein the first phase-change material layer and the second phase-change material layer are each formed as conformal layers at sidewalls of an opening in the insulating layer.
